(19) United States
(12) Patent Application Publication
(10) Pub. No.: US 2026/0190524 A1
(43) Pub. Date: Jul. 2, 2026

(54) SEMICONDUCTOR PACKAGE

(71) Applicant: SAMSUNG ELECTRONICS CO., LTD., Suwon-si (KR)

(72) Inventors: Jun Ho LEE, Suwon-si (KR); Sun Woo HAN, Suwon-si (KR)

(73) Assignee: SAMSUNG ELECTRONICS CO., LTD., Suwon-si (KR)

(21) Appl. No.: 19/423,475

(22) Filed: Dec. 17, 2025

(30) Foreign Application Priority Data
Dec. 26, 2024 (KR) 10-2024-0196707

(51) Int. Cl. H10F 39/00

(52) U.S. Cl. CPC H10F 39/804; H10F 39/811

(57) ABSTRACT

A semiconductor package is provided. a semiconductor package comprises a package substrate, an interposer attached onto the package substrate, a first semiconductor chip attached onto the interposer by a first bonding member, a second bonding member positioned on the interposer and spaced apart from the first semiconductor chip, a cover glass positioned on the second bonding member and an encapsulant encapsulating the package substrate, the interposer, and the cover glass.

This application claims priority from Korean Patent Application No. 10-2024-0196707 filed on December 26, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor package.

### 2. Description of the Related Art

As electronic products trend toward miniaturization, slimming, and higher density, printed circuit boards (PCBs) are becoming smaller and slimmer.

As multilayer PCBs become increasingly slimmer, warpage in the multilayer PCBs may increase. If warpage of the multilayer PCBs increases, semiconductor chips mounted on the multilayer PCBs may also experience warpage.

### SUMMARY

An objective of the present disclosure is to provide a semiconductor package with improved durability.

The objectives of the present disclosure are not limited to those mentioned above, and other objectives not explicitly stated will be clearly understood by those skilled in the art based on the following description.

According to an aspect of the present disclosure, there is provided a semiconductor package comprising a package substrate, an interposer attached onto the package substrate, a first semiconductor chip attached onto the interposer by a first bonding member, a second bonding member positioned on the interposer and spaced apart from the first semiconductor chip, a cover glass positioned on the second bonding member and an encapsulant encapsulating the package substrate, the interposer, and the cover glass.

According to the aforementioned and other embodiments of the present disclosure, a semiconductor package comprising a package substrate, an interposer attached onto the package substrate, a first bonding wire electrically connecting the package substrate and the interposer, a first semiconductor chip attached onto the interposer by a first bonding member, a second bonding wire electrically connecting the interposer and the first semiconductor chip, a second bonding member positioned on the interposer and spaced apart from the first semiconductor chip, a cover glass positioned on the second bonding member and an encapsulant encapsulating the package substrate, the interposer, and the cover glass, wherein the first semiconductor chip includes a first area and a second area surrounding the first area, and the first bonding member is positioned on the second area.

According to the aforementioned and other embodiments of the present disclosure, a semiconductor package comprising a package substrate, an interposer attached onto the package substrate, a first bonding wire electrically connecting the package substrate and the interposer, a first semiconductor chip attached onto the interposer by a first bonding member and including a plurality of active pixel sensors on an upper surface thereof, a second bonding wire electrically connecting the interposer and the first semiconductor chip, a second bonding member positioned on the interposer and spaced apart from the first semiconductor chip, a cover glass positioned on the second bonding member, and an encapsulant encapsulating the package substrate, the interposer, and the cover glass, wherein the first semiconductor chip includes a first area and a second area surrounding the first area, and the first bonding member is positioned on the second area, and includes a first sub-bonding member and a second sub-bonding member spaced apart from each other across the first area and each extending in a first direction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a top view illustrating an image sensor package according to some embodiments of the present disclosure.

FIG. 2 is a cross-sectional view taken along I-I' of FIG. 1.

FIG. 3 is an enlarged view illustrating only region X in FIG. 1.

FIG. 4 is a cross-sectional view illustrating only some components of an image sensor package according to some embodiments of the present disclosure.

FIGS. 5 through 8 are bottom views for explaining some of the components illustrated in FIG. 4 according to various embodiments of the present disclosure.

FIG. 9 is a cross-sectional view illustrating only some components of an image sensor package according to some embodiments of the present disclosure.

FIG. 10 is a bottom view for some of the components illustrated in FIG. 9.

FIG. 11 is a cross-sectional view illustrating only some components of an image sensor package according to some embodiments of the present disclosure.

FIG. 12 is a top view illustrating some of the components illustrated in FIG. 11.

FIG. 13 is a cross-sectional view illustrating only some components of an image sensor package according to some embodiments of the present disclosure.

FIG. 14 is a top view illustrating some of the components illustrated in FIG. 13

### DETAILED DESCRIPTION

The following describes embodiments of the present disclosure in detail with reference to the accompanying drawings. The same reference numerals are used for the same components in the drawings, and redundant descriptions thereof will be omitted.

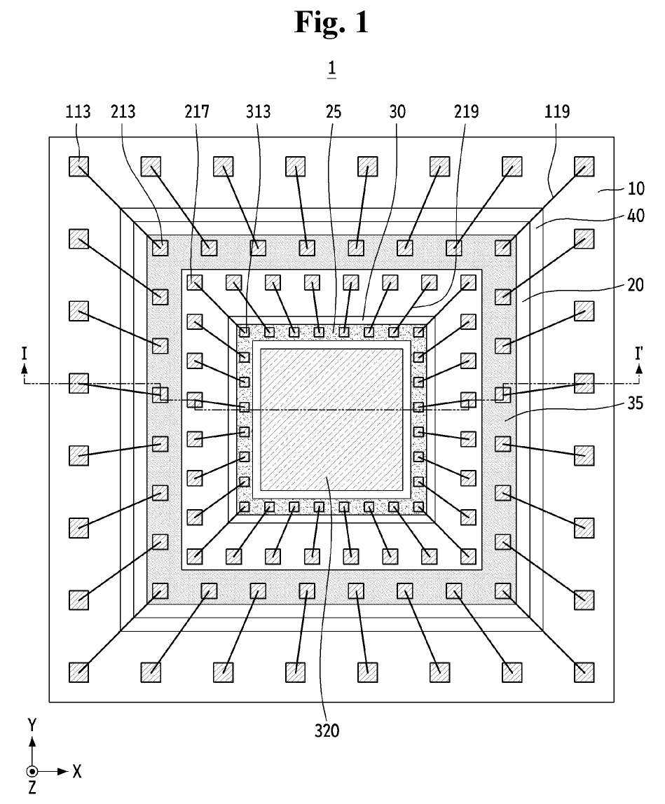

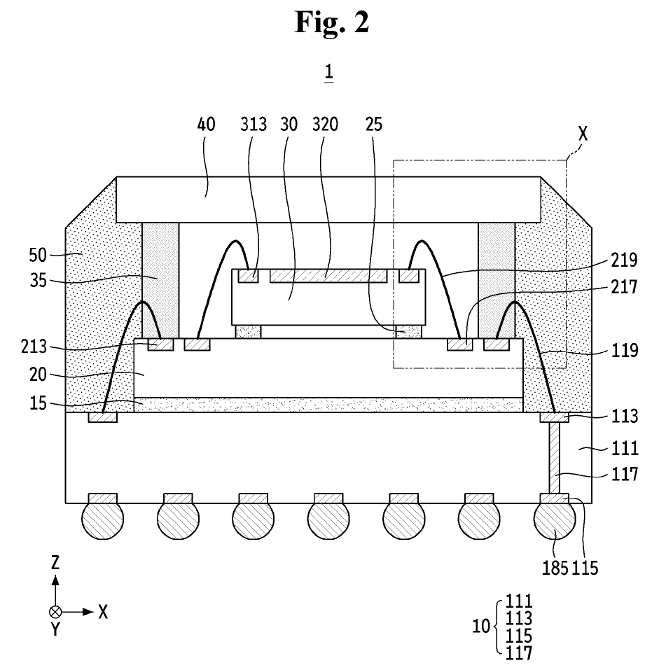

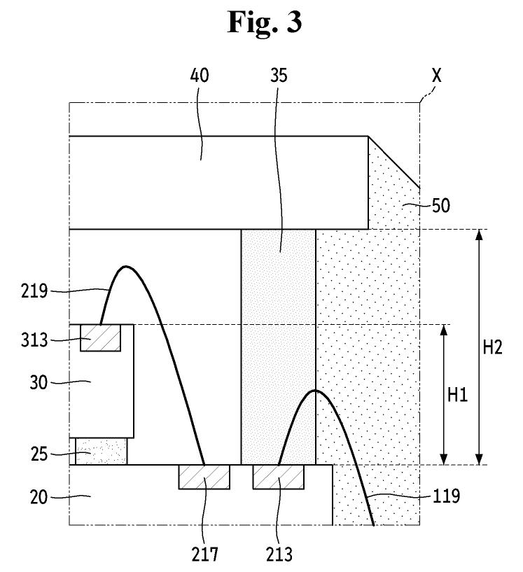

FIG. 1 is a top view illustrating an image sensor package according to some embodiments of the present disclosure. FIG. 2 is a cross-sectional view taken along I-I' of FIG. 1. FIG. 3 is an enlarged view illustrating only region X in FIG. 1.

Referring to FIGS. 1 through 3, a semiconductor package 1 may include a package substrate 10, an interposer 20, a first semiconductor chip 30, a cover glass 40, and an encapsulant 50.

The package substrate 10 may be, for example, a printed circuit board (PCB). The package substrate 10 may include a substrate base 111 that includes at least one selected from a phenol resin, an epoxy resin, and polyimide. In addition, the package substrate 10 may include upper substrate pads 113 positioned on the upper surface of the substrate base 111 and lower substrate pads 115 positioned on the lower surface of the substrate base 111. Inside the substrate base 111, internal wiring patterns 117 may be arranged to electrically connect the upper substrate pads 113 and the lower substrate pads 115. Although not illustrated, the package substrate 10 may further include an upper passivation layer covering the upper surface of the substrate base 111 while exposing the upper substrate pads 113, and a lower passivation layer covering the lower surface of the substrate base 111 while exposing the lower substrate pads 115.

For example, the upper substrate pads 113 and the lower substrate pads 115 may each include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

The upper substrate pads 113 may be regions where conductive connection members electrically connecting the package substrate 10 and the interposer 20 are in contact. For example, first bonding wires 119 may extend between the upper substrate pads 113 of the package substrate 10 and first electrode pads 213 of the first semiconductor chip 30, thereby electrically connecting the first electrode pads 213 of the interposer 20 and the upper substrate pads 113 of the package substrate 10.

The lower substrate pads 115 may be regions where external connection terminals 185 are attached. The external connection terminals 185 may be connected to the lower substrate pads 115 through openings in the lower passivation layer. For example, the external connection terminals 185 may be solder balls. The external connection terminals 185 may electrically connect the semiconductor package 1 and an external device (not illustrated).

In some embodiments, the interposer 20 may be attached to the package substrate 10 by a first bonding member 15.

The interposer 20 may include an upper surface and a lower surface facing each other. In some embodiments, the first bonding member 15 may be in full contact with the lower surface of the interposer 20. For example, the first bonding member 15 may be thermal grease, a thermal pad, or a die attach film.

In some embodiments, the first semiconductor chip 30 may be attached to the interposer 20 by a second bonding member 25. For example, the first semiconductor chip 30 may be an image sensor chip. The upper surface of the first semiconductor chip 30 may include a sensing region 320. The sensing region 320 of the first semiconductor chip 30 may include a pixel array that includes a plurality of unit pixels. The plurality of unit pixels may be arranged in a two-dimensional (2D) array on the upper surface of the first semiconductor chip 30. The plurality of unit pixels may be active pixel sensors. Each of the plurality of unit pixels may include a photodiode for sensing light, a transfer transistor for transferring a charge generated by the photodiode, a floating diffusion region for storing the transferred charge, a reset transistor for periodically resetting the floating diffusion region, and a source follower for buffering a signal corresponding to the charge accumulated in the floating diffusion region. For example, the sensing region 320 may include a CMOS image sensor (CIS) and a charge-coupled device (CCD).

The sensing region 320 of the first semiconductor chip 30 may include a plurality of color filters and a plurality of microlenses sequentially arranged over the plurality of unit pixels. The plurality of color filters may include a red (R) filter, a blue (B) filter, and a green (G) filter. Alternatively, the plurality of color filters may include a cyan (C) filter, a yellow (Y) filter, and a magenta (M) filter. The plurality of microlenses may condense incident light onto the plurality of unit pixels in the sensing region 320. Each of the plurality of unit pixels may detect a component of separated incident light and recognize a single color.

The first semiconductor chip 30 may include an upper surface and a lower surface facing each other. In some embodiments, the second bonding member 25 may be in contact with a portion of the lower surface of the first semiconductor chip 30. Specific details regarding the second bonding member 25 will be described later. For example, the second bonding member 25 may be thermal grease, a thermal pad, or a die attach film.

Second bonding wires 219 may extend between second electrode pads 217 of the interposer 20 and third electrode pads 313 of the first semiconductor chip 30, thereby electrically connecting the second electrode pads 217 of the interposer 20 and the third electrode pads 313 of the first semiconductor chip 30.

Through the first bonding wires 119 and the second bonding wires 219, the first semiconductor chip 30 may receive at least one of a control signal, a power signal, and a ground signal from an external source. Additionally, through the first bonding wires 119 and the second bonding wires 219, the first semiconductor chip 30 may receive a data signal from an external source or output a data signal to an external destination. The first bonding wires 119 and the second bonding wires 219 may include at least one of gold (Au), silver (Ag), Cu, or Al.

In some embodiments, the first bonding wires 119 and the second bonding wires 219 may be connected by either thermo-compression bonding or ultrasonic bonding, or by a thermo-sonic bonding method that combines both thermo-compression and ultrasonic bonding.

A third bonding member 35 may be positioned on the interposer 20, spaced apart from the first semiconductor chip 30, and positioned around the first semiconductor chip 30. For example, the third bonding member 35 may be thermal grease, a thermal pad, or a die attach film. Specific details regarding the third bonding member 35 will be described later.

In some embodiments, the upper surface of the third bonding member 35 may be higher than the upper surface of the first semiconductor chip 30. The upper surface of the first semiconductor chip 30 may have a first height H1 relative to the upper surface of the interposer 20. The upper surface of the third bonding member 35 may have a second height H2 relative to the upper surface of the interposer 20. For example, the first height H1 may be smaller than the second height H2.

Additionally, the third bonding member 35 may fully cover the first electrode pads 213 and be arranged to partially cover the first bonding wires 119. That is, the first bonding wires 119, bonded to the first electrode pads 213, may be connected to the upper substrate pads 113 through the third bonding member 35.

The cover glass 40 may be attached to the third bonding member 35 and placed over the first semiconductor chip 30. The cover glass 40 may include a material with high optical transmittance. For example, the cover glass 40 may include transparent glass or a transparent polymer. In some embodiments, the cover glass 40 may further include a filter that transmits or blocks light in a specific wavelength range.

The encapsulant 50 may be arranged on the package substrate 10 and may surround the interposer 20, the third bonding member 35, and the cover glass 40. Specifically, the encapsulant 50 may be formed to cover the sides of the interposer 20, the sides of the third bonding member 35, and the sides of the cover glass 40. The encapsulant 50 may not cover the upper surface of the cover glass 40 so that the upper surface of the cover glass 40 may be exposed.

For example, the encapsulant 50 may be formed by injecting an insulating resin onto the package substrate 10 and then curing the insulating resin. During the formation of the encapsulant 50, the third bonding member 35 may block the material constituting the encapsulant 50 from entering an internal space between the third bonding member 35 and the cover glass 40. Thus, the encapsulant 50 may be prevented from contacting the first semiconductor chip 30 and filling the space between the sensing region 320 and the cover glass 40. The encapsulant 50 may include an epoxy-based molding resin or a polyimide-based molding resin. For example, the encapsulant 50 may include an epoxy molding compound (EMC).

The encapsulant 50 may be formed to completely cover the first bonding wires 119. Since the encapsulant 50 covers the package substrate 10, the horizontal width of the encapsulant 50 may be substantially the same as the horizontal width of the semiconductor package 1.

As used herein, the expression “substantially the same” may refer to having the same dimension relative to the dimension compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ± 1%, ± 5% , or ± 10% of the actual value stated, and other suitable tolerances.

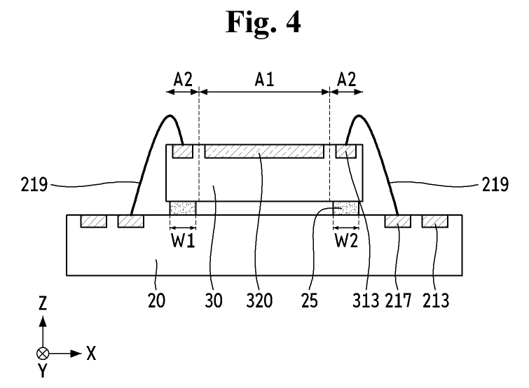

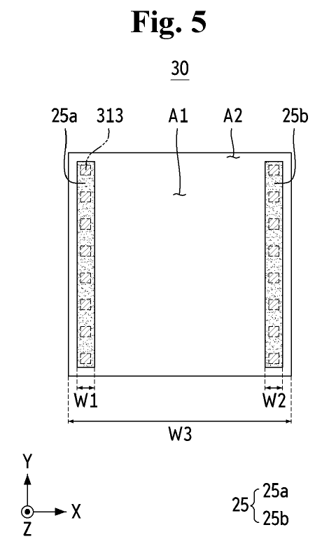

FIG. 4 is a cross-sectional view illustrating only some components of an image sensor package according to some embodiments of the present disclosure. FIGS. 5 through 8 are bottom views for explaining some of the components illustrated in FIG. 4.

Referring to FIGS. 4 and 5, a first semiconductor chip 30 may be attached onto an interposer 20 by a second bonding member 25. The first semiconductor chip 30 may include a first area A1 and a second area A2 surrounding the first area A1. For example, the first area A1 may correspond to a central region of the first semiconductor chip 30, and the second area A2 may be an edge region surrounding the first area A1.

In some embodiments, the second bonding member 25 may be included in the second area A2. The second bonding member 25 may include first and second sub-bonding members 25a and 25b extending in a first direction (or a Y-direction). The first and second sub-bonding members 25a and 25b may be spaced apart from each other across the first area A1.

The first sub-bonding member 25a may have a first width W1 in a second direction (or an X-direction). The second sub-bonding member 25b may have a second width W2 in the second direction (or the X-direction). The first semiconductor chip 30 may have a third width W3 in the second direction (or the X-direction). In some embodiments, the sum of the first and second widths W1 and W2 may range from 5% to 90% of the third width W3. Preferably, the sum of the first and second widths W1 and W2 may range from 5% to 10% of the third width W3. The relationship between the first and second widths W1 and W2 and the third width W3 may minimize the direct contact area between the interposer 20 and the first semiconductor chip 30 without compromising the bonding strength between the interposer 20 and the first semiconductor chip 30. By preventing the first semiconductor chip 30 from directly contacting the package substrate 10 and minimizing the contact area between the first semiconductor chip 30 and the interposer 20, warpage occurring during processing can be reduced. Through this, a semiconductor package 1 with improved durability can be provided.

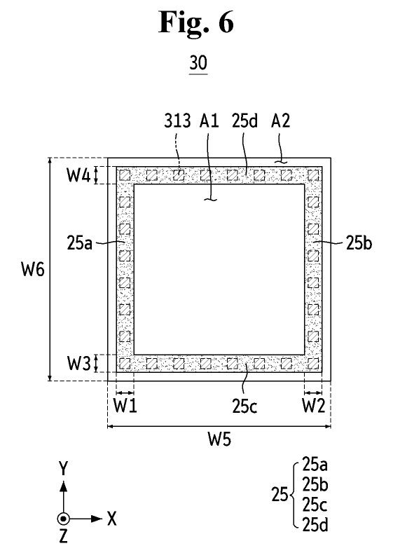

Referring to FIGS. 4 and 6, the first semiconductor chip 30 may be attached onto the interposer 20 by the second bonding member 25. The first semiconductor chip 30 may include a first area A1 and a second area A2 surrounding the first area A1. For example, the first area A1 may correspond to a central region of the first semiconductor chip 30, and the second area A2 may be an edge region surrounding the first area A1.

In some embodiments, the second bonding member 25 may be included in the second area A2. The second bonding member 25 may include first and second sub-bonding members 25a and 25b extending in the first direction (or the Y-direction). The first and second sub-bonding members 25a and 25b may be spaced apart from each other across the first area A1. The second bonding member 25 may also include third and fourth sub-bonding members 25c and 25d extending in the second direction (or the X-direction). The third and fourth sub-bonding members 25c and 25d may be spaced apart from each other across the first area A1. The first through fourth sub-bonding members 25a through 25d may be integrally formed.

The first sub-bonding member 25a may have a first width W1 in the second direction (or the X-direction). The second sub-bonding member 25b may have a second width W2 in the second direction (or the X-direction). The third sub-bonding member 25c may have a third width W3 in the first direction (or the Y-direction). The fourth sub-bonding member 25d may have a fourth width W4 in the first direction (or the Y-direction). The first semiconductor chip 30 may have a fifth width W5 in the second direction (or the X-direction) and a sixth width W6 in the first direction (or the Y-direction).

In some embodiments, the sum of the first and second widths W1 and W2 may range from 5% to 90% of the fifth width W5. Preferably, the sum of the first and second widths W1 and W2 may range from 5% to 10% of the fifth width W5.

In some embodiments, the sum of the third and fourth widths W3 and W4 may range from 5% to 90% of the sixth width W6. Preferably, the sum of the third and fourth widths W3 and W4 may range from 5% to 10% of the sixth width W6.

The relationships between the first and second widths W1 and W2 and the fifth width W5 and between the third and fourth widths W3 and W4 and the sixth width W6 may minimize the direct contact area between the interposer 20 and the first semiconductor chip 30 without compromising the bonding strength between the interposer 20 and the first semiconductor chip 30. By preventing the first semiconductor chip 30 from directly contacting the package substrate 10 and minimizing the contact area between the first semiconductor chip 30 and the interposer 20, warpage occurring during processing can be reduced. Through this, a semiconductor package 1 with improved durability can be provided.

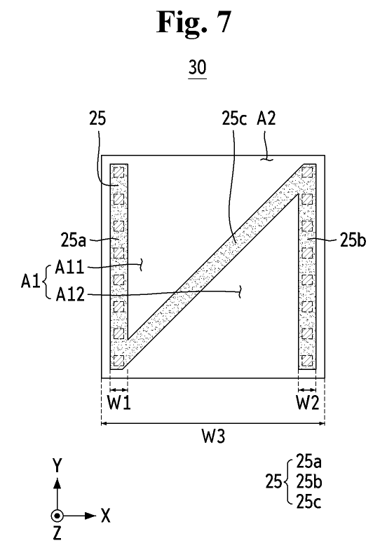

Referring to FIGS. 4 and 7, the first semiconductor chip 30 may be attached onto the interposer 20 by the second bonding member 25. The first semiconductor chip 30 may include a first area A1 and a second area A2 surrounding the first area A1. The first area A1 may include first and second sub-areas A11 and A12.

In some embodiments, the second bonding member 25 may be included in the second area A2. The second bonding member 25 may include first and second sub-bonding members 25a and 25b extending in the first direction (or the Y-direction) and a third sub-bonding member 25c extending in a diagonal direction across the first area A11 and intersecting the first and second sub-bonding members 25a and 25b. The first and second sub-bonding members 25a and 25b may be spaced apart across the first area A11. The first sub-area A11 may be positioned between the first and third sub-bonding members 25a and 25c, and the second sub-area A12 may be positioned between the second and third sub-bonding members 25b and 25c. The first through third sub-bonding members 25a through 25c may be integrally formed.

The first sub-bonding member 25a may have a first width W1 in the second direction (or the X-direction). The second sub-bonding member 25b may have a second width W2 in the second direction (or the X-direction). The first semiconductor chip 30 may have a third width W3 in the second direction (or the X-direction). In some embodiments, the sum of the first and second widths W1 and W2 may range from 5% to 90% of the third width W3. Preferably, the sum of the first and second widths W1 and W2 may range from 5% to 10% of the third width W3. The relationship between the first and second widths W1 and W2 and the third width W3 may minimize the direct contact area between the interposer 20 and the first semiconductor chip 30 without compromising the bonding strength between the interposer 20 and the first semiconductor chip 30. By preventing the first semiconductor chip 30 from directly contacting the package substrate 10 and minimizing the contact area between the first semiconductor chip 30 and the interposer 20, warpage occurring during processing can be reduced. Through this, a semiconductor package 1 with improved durability can be provided.

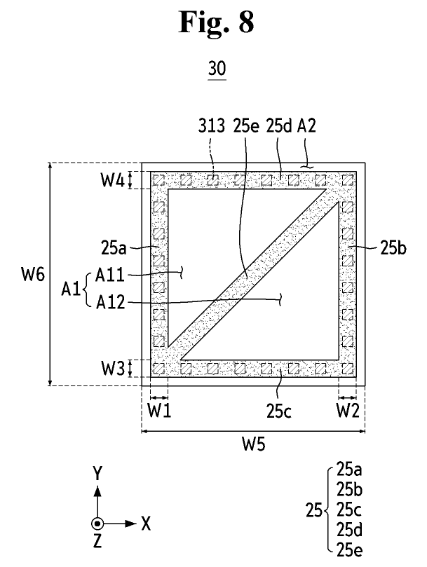

Referring to FIGS. 4 and 8, the first semiconductor chip 30 may be attached onto the interposer 20 by the second bonding member 25. The first semiconductor chip 30 may include a first area A1 and a second area A2 surrounding the first area A1. The first area A1 may include first and second sub-areas A11 and A12.

In some embodiments, the second bonding member 25 may be included in the second area A2. The second bonding member 25 may include first and second sub-bonding members 25a and 25b extending in the first direction (or the Y-direction). Additionally, the second bonding member 25 may include third and fourth sub-bonding members 25c and 25d extending in the second direction (or the X-direction). Further, the second bonding member 25 may include a fifth sub-bonding member 25e extending in a third direction (e.g., a diagonal direction or an XY-direction). The first, fourth, and fifth sub-bonding members 25a, 25d, and 25e may surround the first sub-area A11. The second, third, and fifth sub-bonding members 25b, 25c, and 25e may surround the second sub-area A12. The first through fifth sub-bonding members 25a through 25e may be integrally formed.

The first sub-bonding member 25a may have a first width W1 in the second direction (or the X-direction). The second sub-bonding member 25b may have a second width W2 in the second direction (or the X- direction). The third sub-bonding member 25c may have a third width W3 in the first direction (or the Y-direction). The fourth sub-bonding member 25d may have a fourth width W4 in the first direction (or the Y-direction). The first semiconductor chip 30 may have a fifth width W5 in the second direction (or the X-direction) and a sixth width W6 in the first direction (or the Y-direction).

In some embodiments, the sum of the first and second widths W1 and W2 may range from 5% to 90% of the fifth width W5. Preferably, the sum of the first and second widths W1 and W2 may range from 5% to 10% of the fifth width W5.

In some embodiments, the sum of the third and fourth widths W3 and W4 may range from 5% to 90% of the sixth width W6. Preferably, the sum of the third and fourth widths W3 and W4 may range from 5% to 10% of the sixth width W6.

The relationships between the first and second widths W1 and W2 and the fifth width W5 and between the third and fourth widths W3 and W4 and the sixth width W6 may minimize the direct contact area between the interposer 20 and the first semiconductor chip 30 without compromising the bonding strength between the interposer 20 and the first semiconductor chip 30. By preventing the first semiconductor chip 30 from directly contacting the package substrate 10 and minimizing the contact area between the first semiconductor chip 30 and the interposer 20, warpage occurring during processing can be reduced. Through this, a semiconductor package 1 with improved durability can be provided.

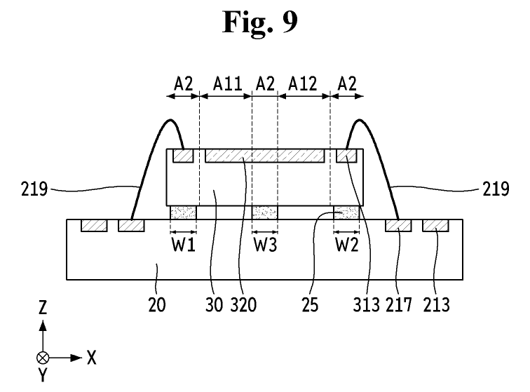

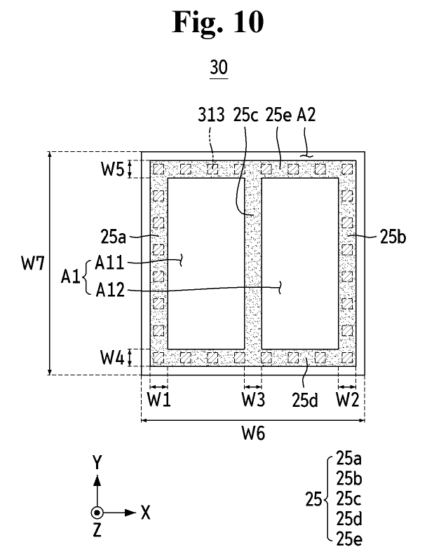

FIG. 9 is a cross-sectional view illustrating only some components of an image sensor package according to some embodiments of the present disclosure. FIG. 10 is a bottom view for some of the components illustrated in FIG. 9.

Referring to FIGS. 9 and 10, a first semiconductor chip 30 may be attached onto an interposer 20 by a second bonding member 25. The first semiconductor chip 30 may include a first area A1 and a second area A2 surrounding the first area A1. The first area A1 may include a first sub-area A11 and a second sub-area A12.

In some embodiments, the second bonding member 25 may be included in the second area A2. The second bonding member 25 may include first, second, and third sub-bonding members 25a, 25b, and 25c extending in a first direction (or a Y-direction). The first and third sub-bonding members 25a and 25c may be spaced apart from each other across the first sub-area A11. The second and third sub-bonding members 25b and 25c may be spaced apart from each other across the second sub-area A12. Additionally, the second bonding member 25 may include fourth and fifth sub-bonding members 25d and 25e extending in a second direction (or an X-direction). The fourth and fifth sub-bonding members 25d and 25e may be spaced apart from each other across the first and second sub-areas A11 and A12. The first through fifth sub-bonding members 25a through 25e may be integrally formed.

The first sub-bonding member 25a may have a first width W1 in the second direction (or the X-direction). The second sub-bonding member 25b may have a second width W2 in the second direction (or the X-direction). The third sub-bonding member 25c may have a third width W3 in the second direction (or the X-direction). The fourth sub-bonding member 25d may have a fourth width W4 in the first direction (or the Y-direction). The fifth sub-bonding member 25e may have a fifth width W5 in the first direction (or the Y-direction). The first semiconductor chip 30 may have a sixth width W6 in the second direction (or the X-direction) and a seventh width W7 in the first direction (or the Y-direction).

In some embodiments, the sum of the first, second, and third widths W1, W2, and W3 may range from 5% to 90% of the sixth width W6. Preferably, the sum of the first, second, and third widths W1, W2, and W3 may range from 5% to 10% of the sixth width W6.

In some embodiments, the sum of the fourth and fifth widths W4 and W5 may range from 5% to 90% of the seventh width W7. Preferably, the sum of the fourth and fifth widths W4 and W5 may range from 5% to 10% of the seventh width W7.

The relationships between the first, second, and third widths W1, W2, and W3 and the sixth width W6 and between the fourth and fifth widths W4 and W5 and the seventh width W7 may minimize the direct contact area between the interposer 20 and the first semiconductor chip 30 without compromising the bonding strength between the interposer 20 and the first semiconductor chip 30. By preventing the first semiconductor chip 30 from directly contacting the package substrate 10 and minimizing the contact area between the first semiconductor chip 30 and the interposer 20, warpage occurring during processing can be reduced. Through this, a semiconductor package 1 with improved durability may be provided.

As one exemplary measurement method of the aforementioned widths, a “width” of a component between two targeted surfaces of the component may mean an average value of shortest distances between the two targeted surfaces measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

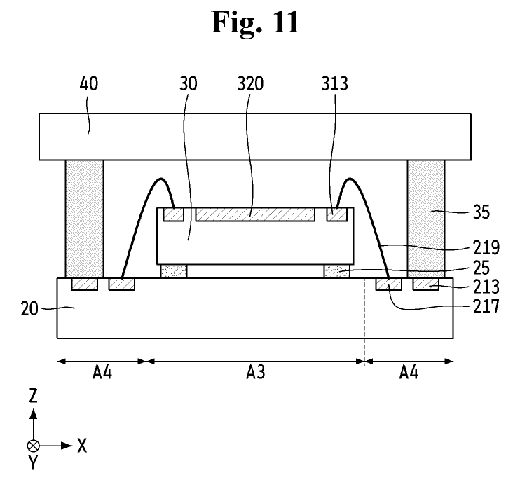

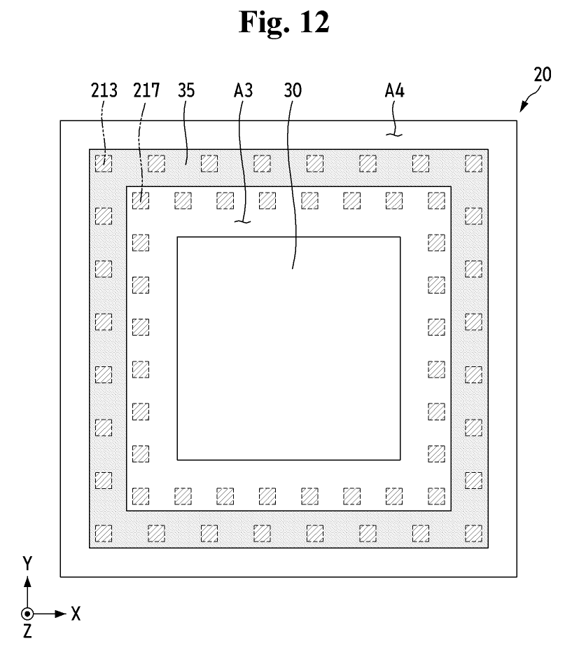

FIG. 11 is a cross-sectional view illustrating only some components of an image sensor package according to some embodiments of the present disclosure. FIG. 12 is a top view illustrating some of the components illustrated in FIG. 11.

Referring to FIGS. 11 and 12, a semiconductor package 1 may include a first semiconductor chip 30 and a third bonding member 35, on an interposer 20. The interposer 20 may include a third area A3 and a fourth area A4 surrounding the third area A3. For example, the third area A3 may correspond to a central region of the interposer 20, and the fourth area A4 may be an edge region surrounding the third area A3.

In some embodiments, the first semiconductor chip 30 may be positioned on the third area A3. The third bonding member 35 may be positioned on the fourth area A4.

The third bonding member 35 may have a rectangular ring shape extending continuously along the edges of the interposer 20. The third bonding member 35 may be placed around the first semiconductor chip 30 at a predetermined distance from the first semiconductor chip 30.

In some embodiments, the upper surface of the third bonding member 35 may be higher than the upper surface of the first semiconductor chip 30. In addition, the third bonding member 35 may be arranged to completely cover first electrode pads 213. However, the third bonding member 35 may not contact second electrode pads 217.

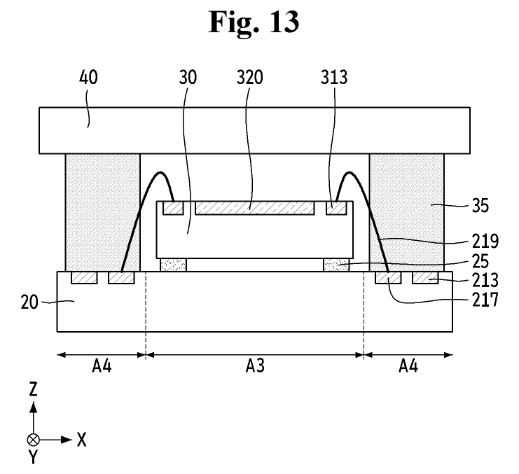

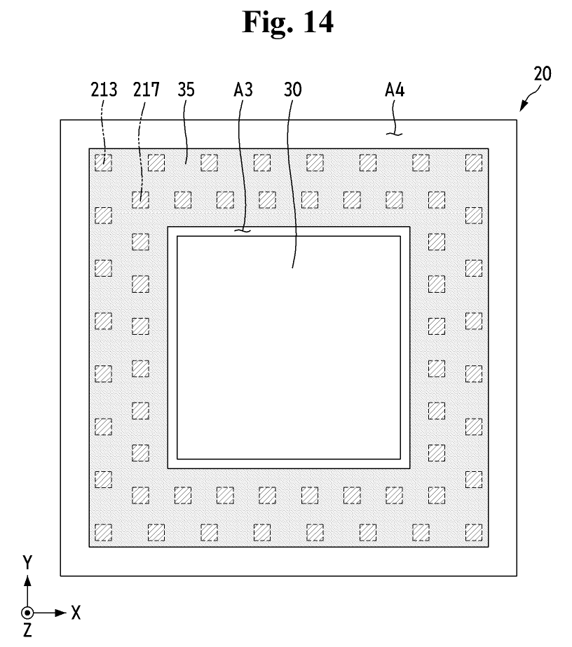

FIG. 13 is a cross-sectional view illustrating only some components of an image sensor package according to some embodiments of the present disclosure. FIG. 14 is a top view illustrating some of the components illustrated in FIG. 13.

Referring to FIGS. 13 and 14, a semiconductor package 1 may include a first semiconductor chip 30 and a third bonding member 35 on an interposer 20. The interposer 20 may include a third area A3 and a fourth area A4 surrounding the third area A3. For example, the third area A3 may correspond to a central region of the interposer 20, and the fourth area A4 may be an edge region surrounding the third area A3.

In some embodiments, the first semiconductor chip 30 may be positioned on the third area A3. The third bonding member 35 may be positioned on the fourth area A4.

The third bonding member 35 may have a rectangular ring shape extending continuously along the edges of the interposer 20. The third bonding member 35 may be placed around the first semiconductor chip 30 at a predetermined distance from the first semiconductor chip 30.

In some embodiments, the upper surface of the third bonding member 35 may be higher than the upper surface of the first semiconductor chip 30. In addition, the third bonding member 35 may be arranged to completely cover first electrode pads 213 and second electrode pads 217.

Although the embodiments of the present disclosure have been described with reference to the accompanying drawings, the present disclosure is not limited to these embodiments and may be manufactured in various other forms. Those skilled in the art will understand that the technical scope or essential characteristics of the present disclosure can be modified and implemented in other specific forms without departing from the spirit of the invention. Therefore, the embodiments described above should be understood as being illustrative in all respects and not limiting.

What is claimed is:

1. A semiconductor package comprising:
a package substrate;
an interposer attached onto the package substrate;
a first semiconductor chip attached onto the interposer by a first bonding member;
a second bonding member positioned on the interposer and spaced apart from the first semiconductor chip;
a cover glass positioned on the second bonding member; and
an encapsulant encapsulating the package substrate, the interposer, and the cover glass.

2. The semiconductor package of claim 1, wherein
the first semiconductor chip includes a first area and a second area surrounding the first area, and
the first bonding member is positioned in the second area.

3. The semiconductor package of claim 2, wherein
from a planar view of the semiconductor package, the first bonding member includes a plurality of sub-bonding members, and
a sum of widths of the sub-bonding members in a first direction is from 5% to 90% of a width of the first semiconductor chip in the first direction.

4. The semiconductor package of claim 3, wherein the plurality of sub-bonding members include a first sub-bonding member and a second sub-bonding member spaced apart from each other across the first area and each extending in a second direction intersecting the first direction.

5. The semiconductor package of claim 4, wherein the plurality of sub-bonding members further include a third sub-bonding member and a fourth sub-bonding member spaced apart from each other across the first area and intersecting the first sub-bonding member and the second sub-bonding member.

6. The semiconductor package of claim 4, wherein
the first area includes a first sub-area and a second sub-area, and
the first sub-area and the second sub-area are separated by a portion of the first bonding member.

7. The semiconductor package of claim 1, further comprising:
a first bonding wire electrically connecting the package substrate and the interposer; and
a second bonding wire electrically connecting the interposer and the first semiconductor chip.

8. The semiconductor package of claim 7, wherein the second bonding member covers a portion of the first bonding wire that contacts the interposer.

9. The semiconductor package of claim 8, wherein the second bonding member surrounds a portion of the second bonding wire that contacts the first semiconductor chip.

10. The semiconductor package of claim 1, wherein the first semiconductor chip includes a plurality of active pixel sensors on an upper surface thereof.

11. The semiconductor package of claim 1, wherein an upper surface of the second bonding member is positioned higher than an upper surface of the first semiconductor chip.

12. The semiconductor package of claim 1, wherein
the interposer includes a third area and a fourth area surrounding the third area,
the first semiconductor chip is positioned on the third area, and
the second bonding member is positioned on the fourth area.

13. A semiconductor package comprising:
a package substrate;
an interposer attached onto the package substrate;
a first bonding wire electrically connecting the package substrate and the interposer;
a first semiconductor chip attached onto the interposer by a first bonding member;
a second bonding wire electrically connecting the interposer and the first semiconductor chip;
a second bonding member positioned on the interposer and spaced apart from the first semiconductor chip;
a cover glass positioned on the second bonding member; and
an encapsulant encapsulating the package substrate, the interposer, and the cover glass,
wherein:
the first semiconductor chip includes a first area and a second area surrounding the first area, and
the first bonding member is positioned on the second area.

14. The semiconductor package of claim 13, wherein the first semiconductor chip includes a plurality of active pixel sensors on an upper surface thereof.

15. The semiconductor package of claim 14, wherein
from a planar view of the semiconductor package, the first bonding member includes a plurality of sub-bonding members, and
a sum of widths of the sub-bonding members in a first direction is from 5% to 90% of a width of the first semiconductor chip in the first direction.

16. The semiconductor package of claim 15, wherein the plurality of sub-bonding members include a first sub-bonding member and a second sub-bonding member spaced apart from each other across the first area and each extending in a second direction intersecting the first direction.

17. The semiconductor package of claim 16, wherein the plurality of sub-bonding members further include a third sub-bonding member and a fourth sub-bonding member spaced apart from each other across the first area and intersecting the first sub-bonding member and the second sub-bonding member.

18. The semiconductor package of claim 16, wherein
the first area includes a first sub-area and a second sub-area, and
the first sub-area and the second sub-area are separated by a portion of the first bonding member.

19. The semiconductor package of claim 13, wherein
the interposer includes a third area and a fourth area surrounding the third area,
the first semiconductor chip is positioned on the third area, and
the second bonding member is positioned on the fourth area.

20. A semiconductor package comprising:
a package substrate;
an interposer attached onto the package substrate;
a first bonding wire electrically connecting the package substrate and the interposer;
a first semiconductor chip attached onto the interposer by a first bonding member and including a plurality of active pixel sensors on an upper surface thereof;
a second bonding wire electrically connecting the interposer and the first semiconductor chip;
a second bonding member positioned on the interposer and spaced apart from the first semiconductor chip;
a cover glass positioned on the second bonding member; and
an encapsulant encapsulating the package substrate, the interposer, and the cover glass,
wherein
the first semiconductor chip includes a first area and a second area surrounding the first area, and
the first bonding member is positioned on the second area, and includes a first sub-bonding member and a second sub-bonding member spaced apart from each other across the first area and each extending in a first direction.
